(19) United States
(12) Patent Application Publication
(10) Pub. No.: US 2008/0303047 A1
(43) Pub. Date: Dec. 11, 2008

(54) Light-emitting diode device and manufacturing method therof

(75) Inventors: Chien-Fu Shen, Hsinchu (TW); De-Shan Kuo, Hsinchu (TW); Cheng-Ta Kuo, Hsinchu (TW)

Correspondence Address: BACON & THOMAS, PLLC, 625 SLATERS LANE, FOURTH FLOOR, ALEXANDRIA, VA, 22314-1176, US

(73) Assignee: EPISTAR CORPORATION, Hsinchu (TW)

(21) Appl. No.: 12/153,098

(22) Filed: May 14, 2008

(30) Foreign Application Priority Data
May 15, 2007 (TW) 96117271

(51) Int. Cl. H01L 33/00; H01L 21/02

(52) U.S. Cl. 257/98; 438/29; 257/E21.002; 257/E33.069; 257/E33.073

(57) ABSTRACT

A light-emitting diode (LED) device and manufacturing methods thereof are disclosed, wherein the LED device comprises a substrate, a plurality of micro-lens, a reflector, a first conductivity type semiconductor layer, an active layer, a second conductivity type semiconductor layer, a first electrode and a second electrode. The substrate has a plurality of micro-lens on its upper surface. The first conductivity type semiconductor layer is on the upper surface of the substrate. The active layer and the second conductivity type semiconductor layer are sequentially on a portion of the first conductivity type semiconductor layer. The first electrode is on the other portion of the first conductivity type semiconductor layer uncovered by the active layer. The second electrode is on the second conductivity type semiconductor layer. The reflector layer is on a lower surface of the substrate.

### CROSS REFERENCE TO RELATED APPLICATIONS

This application claims the right of priority based on Taiwan Patent Application No. 096117271 entitled “LIGHT-EMITTING DIODE DEVICE AND MANUFACTURING METHOD THEROF”, filed on May 15, 2007, which is incorporated herein by reference and assigned to the assignee herein.

### TECHNICAL FIELD

This present disclosure relates to a light-emitting diode device and a method of forming the same, especially a light-emitting diode device with a micro-lens substrate and a method of forming the same.

### BACKGROUND OF THE DISCLOSURE

The light-emitting diode devices are low electricity consumption, low heat generation, long life-time, shockproof, small in volume, and have rapid response and good opto-electrical property like emitting stable wavelength light and so on, thus have been widely applied in household appliances, instrument indicator lights and opto-electrical products. As the opto-electrical technology progresses, the solid state light-emitting devices are improved as well in light efficiency, life-time and brightness, and will be the mainstream in the near future.

The light generated from the active layer of the light-emitting diode device can not emit to the environment from the surface of light-emitting diode device because of the total reflection caused by the light incidence angle larger than the critical angle of the interface, and the light extraction efficiency of the light-emitting diode device is reduced.

In order to solve the problem, a three-dimensional transparent geometric pattern is formed on the epitaxy structure of the light-emitting diode device by etching, deposition and adhering processes. The pattern can scatter the light and then enlarge the incident angle, so the light extraction efficiency of the light-emitting diode device is improved. However, those etching, deposition and adhering processes can damage the surface of the epitaxy structure. Therefore, a new fabricating method of a light-emitting diode device method that can protect the surface of the epitaxy structure and enhance the light extraction efficiency of the light-emitting diode device is required.

### SUMMARY OF THE DISCLOSURE

One embodiment of the present disclosure provides a light-emitting diode device with high light extraction efficiency, including a micro-lens substrate, a reflector, a buffer layer, a first conductivity type semiconductor layer, an active layer, a second conductivity type semiconductor layer, a first electrode, and a second electrode. The micro-lens substrate has a plurality of micro-lens on its upper surface. The buffer layer is on the micro-lens substrate. The first conductivity type semiconductor layer is on the buffer layer. The active layer is on a partial area of the first conductivity type semiconductor layer. The second conductivity type semiconductor layer is on the active layer. The first electrode is on another partial area of the first conductivity type semiconductor layer uncovered by the active layer. The second electrode is on the second conductivity type semiconductor layer. The reflector is on the lower surface of the micro-lens substrate.

Another embodiment of the present disclosure provides a light-emitting diode device with high light extraction efficiency, including a micro-lens substrate, a reflector, a buffer layer, a first conductivity type semiconductor layer, an active layer, a second conductivity type semiconductor layer, a first electrode, and a second electrode. The micro-lens substrate has a plurality of micro-lens on its lower surface. The buffer layer is on the upper surface of the micro-lens substrate. The first conductivity type semiconductor layer is on the buffer layer. The active layer is on a partial area of the first conductivity type semiconductor layer. The second conductivity type semiconductor layer is on the active layer. The first electrode is on another partial area of the first conductivity type semiconductor layer uncovered by the active layer. The second electrode is on the second conductivity type semiconductor layer. The reflector is on the lower surface of the micro-lens substrate.

Another embodiment of the present disclosure provides a method for fabricating a light-emitting diode device that does not damage the epitaxy structure and can enhance light extraction efficiency. A method for fabricating a light-emitting diode device comprises the steps of providing a micro-lens substrate having a plurality of micro-lens on its upper surface; forming a buffer layer on the upper surface of the micro-lens substrate; forming a first conductivity type semiconductor layer on the buffer layer; forming an active layer on the first conductivity type semiconductor layer; forming a second conductivity type semiconductor layer on the active layer; removing a portion of the second conductivity type semiconductor layer and a portion of the active layer, exposed a portion of the first conductivity type semiconductor layer; forming a first electrode on the exposed portion of the first conductivity type semiconductor layer; forming a second electrode on the second conductivity type semiconductor layer; and forming a reflector on a lower surface of the micro-lens substrate.

Another embodiment of the present disclosure provides a method for fabricating a light-emitting diode device that does not damage the epitaxy structure and can enhance light extraction efficiency. A method for fabricating a light-emitting diode device comprises the steps of providing a micro-lens substrate having a plurality of micro-lens on its lower surface; forming a buffer layer on an upper surface of the micro-lens substrate; forming a first conductivity type semiconductor layer on the buffer layer; forming an active layer on the first conductivity type semiconductor layer; forming a second conductivity type semiconductor layer on the active layer; removing a portion of the second conductivity type semiconductor layer and a portion of the active layer, exposed a portion of the first conductivity type semiconductor layer; forming a first electrode on the exposed portion of the first conductivity type semiconductor layer; forming a second electrode on the second conductivity type semiconductor layer; and forming a reflector on a lower surface of the micro-lens substrate.

According to the above embodiments of the present disclosure, a method of forming a light emitting diode device is further disclosed by providing a transparent substrate with a plurality of micro-lens, growing the epitaxy structure on the substrate, and forming a reflector below the substrate. The light emitting from the active layer of the epitaxy structure can change the incidence angle after being reflected and/or scattered by the reflector and micro-lens, and the light extraction efficiency of the light-emitting diode device is enhanced accordingly.

### BRIEF DESCRIPTION OF THE DRAWINGS

The foregoing aspects and many of the attendant advantages of this disclosure are more readily appreciated as the same becomes better understood by reference to the following detailed description, when taken in conjunction with the accompanying drawings, wherein:

FIGS. 1A-1D are the series of processing section diagrams of the first embodiment of the present disclosure related to a gallium nitride light-emitting diode device 100.

FIGS. 2A-2D are the series of processing section diagrams of the second embodiment of the present disclosure related to a gallium nitride light-emitting diode device 200.

FIGS. 3A-3D are the series of processing section diagrams of the third embodiment of the present disclosure related to a gallium nitride light-emitting diode device 300.

FIGS. 4A-4D are the series of processing section diagrams of the forth embodiment of the present disclosure related to a gallium nitride light-emitting diode device 400.

### DETAILED DESCRIPTION OF THE PREFERRED EMBODIMENTS

A light-emitting diode device and manufacturing methods thereof that do not damage the epitaxy structure and can enhance light extraction efficiency are disclosed. In order to understand easily the above and other purposes, characterizations and advantages of the present disclosure, although specific embodiments have been illustrated and described, it will be apparent that various modifications may fall within the scope of the appended claims.

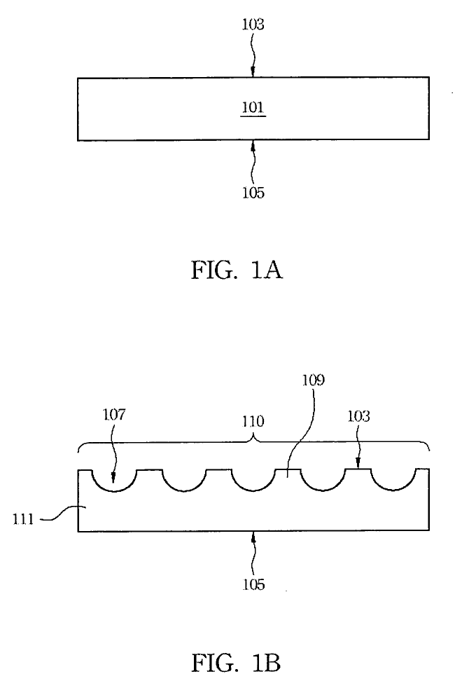

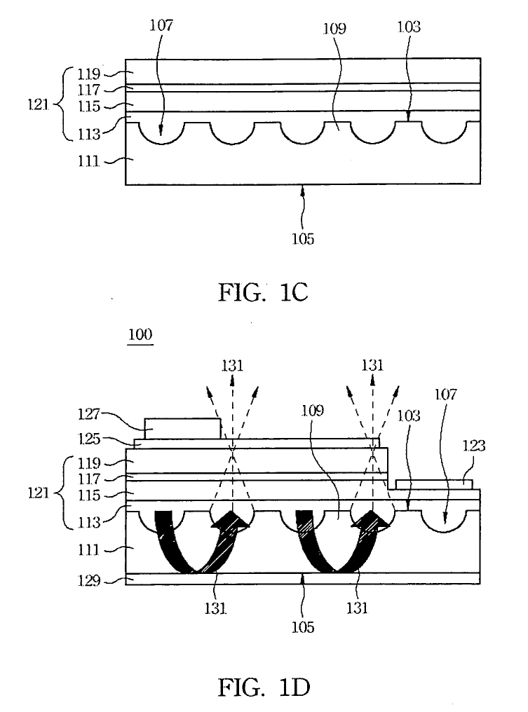

FIGS. 1A-1D are the series of processing section diagrams of the first embodiment of the present disclosure related to a gallium nitride light-emitting diode device 100. First, FIG. 1A shows that a transparent substrate 101 having an upper surface 103 and a lower surface 105 is provided. Then the upper surface 103 is etched to form a plurality of concaves 107 as shown in FIG. 1B. The preferred embodiment of the present disclosure discloses that the un-etched regions of the upper surface 103 form a plurality of protrusions 109 shaped in semi-sphere, pyramidal, trapezoid, curve, cone or other shapes that can pass and/or scatter the light. These protrusions 109 are continuously or discontinuously disposed to form a geometric pattern 110 on the upper surface 103. Every protrusion 109 can be regarded as a micro-lens with light scattering function, thus a micro-lens substrate 111 is formed by the above mentioned processes. In this embodiment, the geometric pattern 110 is composed of a plurality of pyramidal protrusions 109 that have a platform portion and are arranged periodically and continuously as shown in FIG. 1B.

FIG. 1C shows that a buffer layer 113 is formed on the upper surface 103 of the micro-lens substrate 111 by a deposition method, and covers the micro-lens substrate 111 conformally with the geometric pattern 110. In the embodiment of the present disclosure, the buffer layer 113 is AlN or GaN. Then growing a first conductivity type (for example n-type) semiconductor layer 115 on the buffer layer 113 by for example the metal organic chemical vapor deposition technology with the reaction gases like trimethylgallium (TMGa), trimethylaluminun (TMAl), trimethylindinum (TMIn), ammonia gas and the above gases arbitrarily combined, and adding an n-type dopant like silicon. The preferred material for the first conductivity type semiconductor layer is n-type AlGaInN or n-type GaN. Then growing an active layer 117 on the first conductivity type semiconductor layer 115 wherein the active layer 117 can be composed of AlGaInN or GaN multi-quantum wells structure. After forming the active layer, growing a second conductivity type (for example p-type) semiconductor layer 119 on the active layer 117 by the reaction gases like trimethylgallium (TMGa), trimethylaluminun (TMAl), trimethylindinum (TMIn), ammonia gas and the above gases arbitrarily combined, and adding a p-type dopant like magnesium. The above formation processes of the epitaxy structure on the micro-lens substrate are finished.

Afterwards, an etching process like the transformer coupled plasma (TCP) is performed to expose a portion of the first conductivity type semiconductor layer 115 by removing a portion of the second conductivity type semiconductor layer 119 and a portion of the active layer 117, and then forming the first electrode 123 on the exposed portion of the first conductivity type semiconductor layer. The material of the first electrode 123 in the preferred embodiment of the present disclosure is selected from the group consisting of In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Au/Ni, Ni/Cr/Au, Ti/Pd/Au, Ti/Pt/Au, Ti/Al/Ni/Au, Au/Si/Ti/Au/Si, and Au/Ni/Ti/Si/Ti.

Later, a transparent conductive layer 125 is formed on the second conductivity type semiconductor layer 119, and a second electrode 127 is formed on the transparent conductive layer 125. The material of the transparent conductive layer 125 in the preferred embodiment of the present disclosure is selected from the group consisting of the Indium Tin Oxide, Cadmium Tin Oxide, Zinc Oxide, Indium Oxide, Tin Oxide, Copper Aluminum Oxide, Copper Gallium Oxide, and Strontium Copper Oxide. The second electrode 127 material is selected from the group consisting of Au/Ni, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, Ni/In, and Pt₃In₇.

Afterwards, a reflector layer 129 is formed on the lower surface 105 of the micro-lens substrate 111 to compose a light-emitting diode device 100 as shown in FIG. 1D. In a preferred embodiment of the present disclosure, the reflector layer 129 comprises a Distributed Bragg Reflector (DBR) formed by a stack structure of multi-layered oxide films, a one dimension photonic crystal film and a metal material selected from the group consisting of Al, Au, Pt, Pb, Ag, Ni, Ge, In, Sn and alloys thereof.

The light 131 emitted from the active layer 117 of the light-emitting diode device 100 is reflected by the reflector layer 129, and refracted through the arc surface of the concave portion 107 which can change the emitting angle and the emitting path. After the reflection and the refraction, the light emitting angle is larger than the critical angle between the interface of the transparent conductive layer 125 and the environment, so the light can emit outwardly. The light extraction efficiency of the light-emitting diode device 100 is therefore enhanced.

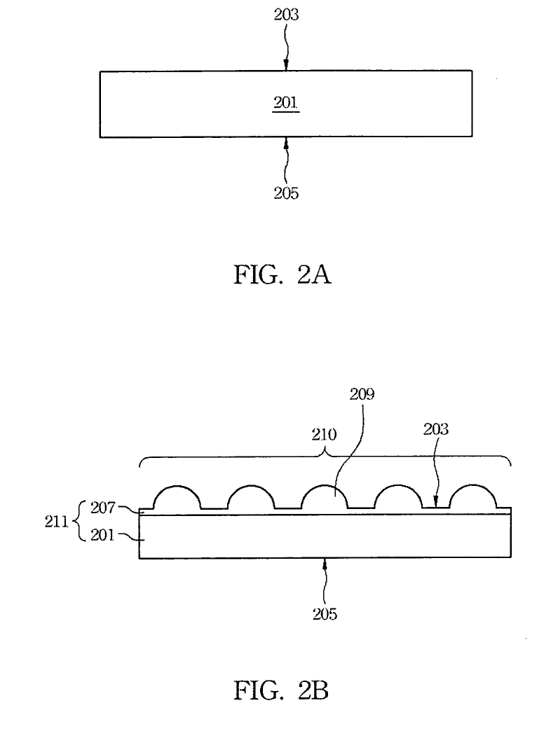

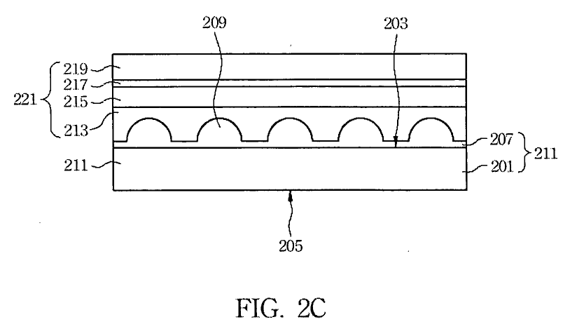

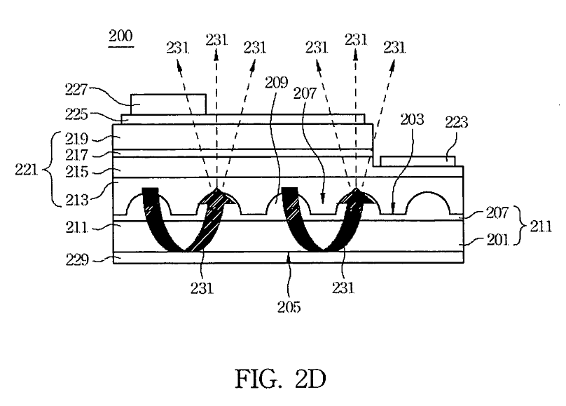

FIGS. 2A-2D are the series of processing section diagrams of the second embodiment of the present disclosure related to a gallium nitride light-emitting diode device 200. First, FIG. 2A shows that a transparent substrate 201 having an upper surface 203 and a lower surface 205 is provided. Then a plurality of protruded particles 209 with transmitting and scattering function is formed on the upper surface 203 by deposition or adhesion process. In the preferred embodiment of the present disclosure, the plurality of protruded particles 209 is insulated and is deposited on the upper surface 203, and the material can be Silicon Oxide, Silicon Di-oxide and Silicon Nitride. In another embodiment of the present disclosure, the protruded particles 209 are fixed on a transparent film 207, and are adhered on the upper surface 203. The shape of the protruded particles 209 can be semi-sphere, pyramidal or trapezoid. These protruded particles 209 are continuously or discontinuously disposed to form a geometric pattern 210 on the upper surface 203. Every protruded particle 209 can be regarded as a micro-lens with scattering function, thus a micro-lens substrate is formed by above mentioned processes. In this embodiment, the geometric pattern 210 is composed of a plurality of semi-sphere protruded particles 209 that are arranged periodically and continuously as shown in FIG. 2B.

As FIG. 2C shows that a buffer layer 213 is formed on the upper surface 203 of micro-lens substrate 211 by a deposition method, and covers the micro-lens substrate 211 confommally with the geometric pattern 210. In the preferred embodiment of the present disclosure, the buffer layer 213 is AlN or GaN. Then growing a first conductivity type (for example n-type) semiconductor layer 215 on the buffer layer 213 by for example the metal organic chemical vapor deposition technology with the reaction gases like trimethylgallium (TMGa), trimethylaluminun (TMAl), trimethylindinum (TMIn), ammonia gas and the above gases arbitrarily combined, and adding an n-type dopant like silicon. The preferred material for the first conductivity type semiconductor layer is n-type AlGaInN or n-type GaN. Then growing an active layer 217 on the first conductivity type semiconductor layer 215 wherein the active layer 217 can be composed of AlGaInN or GaN multi-quantum wells (MQW) structure. After forming the active layer, growing a second conductivity type (for example p-type) semiconductor layer 219 on the active layer 217 with the reaction gases like trimethylgallium (TMGa), trimethylaluminun (TMAl), trimethylindinum (TMIn), ammonia gas and the above gases arbitrarily combined, and adding a p-type dopant like magnesium. The above processes of forming the epitaxy structure on the micro-lens substrate are finished.

Afterwards, an etching process like the transformer coupled plasma (TCP) is performed to expose a portion of the first conductivity type semiconductor layer 215 by removing a portion of the second conductivity type semiconductor layer 219 and a portion of the active layer 217, and then forming the first electrode 223 on the exposed portion of the first conductivity type semiconductor layer. The material of the first electrode 223 in the preferred embodiment of the present disclosure is selected from the group consisting of In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Au/Ni, Ni/Cr/Au, Ti/Pd/Au, Ti/Pt/Au, Ti/Al/Ni/Au, Au/Si/Ti/Au/Si, and Au/Ni/Ti/Si/Ti.

Later, a transparent conductive layer 225 is formed on the second conductivity type semiconductor layer 219, and a second electrode 227 is formed on the transparent conductive layer 225. The material of the transparent conductive layer 225 in the preferred embodiment of the present disclosure is selected from the group consisting of the Indium Tin Oxide, Cadmium Tin Oxide, Zinc Oxide, Indium Oxide, Tin Oxide, Copper Aluminum Oxide, Copper Gallium Oxide, and Strontium Copper Oxide. The second electrode 227 material is selected from the group consisting of Au/Ni, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, Ni/In, and Pt3In7.

Afterwards, a reflector layer 229 is formed on the lower surface 205 of the micro-lens substrate 211 to compose a light-emitting diode device 200 as shown in FIG. 2D. In a preferred embodiment of the present disclosure, the reflector layer 229 comprises a Distributed Bragg Reflector (DBR) formed by a stack structure of multi-layered oxide films, a one dimension photonic crystal film and a metal material selected from the group consisting of Al, Au, Pt, Pb, Ag, Ni, Ge, In, Sn and alloys thereof.

The light 231 emitted from the active layer 217 of the light-emitting diode device 200 is reflected by the reflector layer 229, and refracted through the arc surface of the protruded particles 209 which can change the emitting angle and the emitting path. After the reflection and the refraction, the light emitting angle is larger than the critical angle between the interface of the transparent conductive layer 225 and the environment, so the light can emit outwardly. The light extraction efficiency of the light-emitting diode device 200 is therefore enhanced.

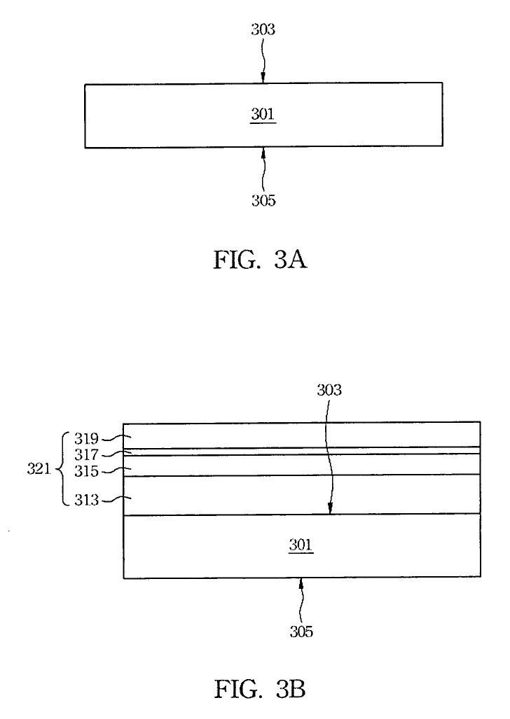

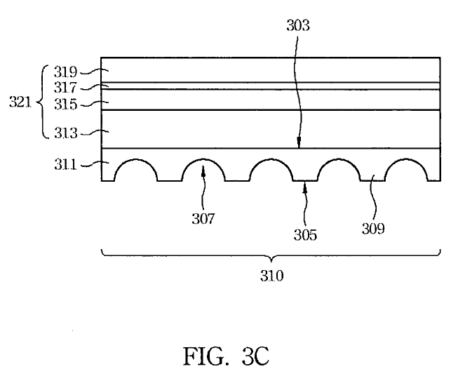

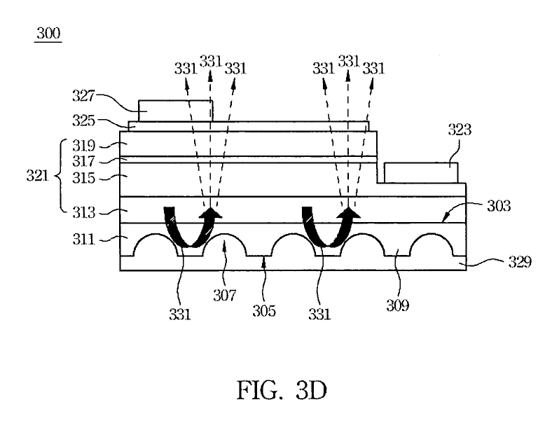

FIGS. 3A-3D are the series of processing section diagrams of the third embodiment of the present disclosure related to a gallium nitride light-emitting diode device 300. First, FIG. 3A shows that a transparent substrate 301 having an upper surface 303 and a lower surface 305 is provided. As FIG. 3B shows that a buffer layer 313 is formed on the upper surface 303 of the transparent substrate 301 by a deposition method. In the preferred embodiment of the present disclosure, the buffer layer 313 is AlN or GaN.

Then growing a first conductivity type (for example n-type) semiconductor layer 315 on the buffer layer 313 by for example the metal organic chemical vapor deposition technology with the reaction gases like trimethylgallium (TMGa), trimethylaluminun (TMAl), trimethylindinum (TMIn), ammonia gas and the above gases arbitrarily combined, and adding an n-type doptant like silicon. The preferred material for the first conductivity type semiconductor layer is n-type AlGaInN or n-type GaN. Then growing an active layer 317 on the first conductive type semiconductor layer 315 wherein the active layer 317 can be composed of AlGaInN or GaN multi-quantum wells (MQW) structure.

After forming the active layer, growing a second conductivity type (for example p-type) semiconductor layer 319 on the active layer 317 with the reaction gases like trimethylgallium (TMGa), trimethylaluminun (TMAl), trimethylindinum (TMIn), ammonia gas and the above gases arbitrarily combined, and adding a p-type dopant like magnesium. The above formation processes of the epitaxy structure on the micro-lens substrate are finished. Then etching the lower surface 305 to form a plurality of concave portions 307 as shown in FIG. 3C. The preferred embodiment of the present disclosure disclosed that the un-etched regions of the lower surface 305 form a plurality of protrusions 309 shaped in semi-sphere, pyramidal, trapezoid, curve, cone or other shapes that can pass and/or scatter the light. These protrusions 309 are continuously or discontinuously disposed to form a geometric pattern 310 on the lower surface 305. Every protrusion 309 can be regarded as a micro-lens with light scattering function, thus a micro-lens substrate 311 is formed by above mentioned processes. In this embodiment, the geometric pattern 310 is composed of a plurality of pyramidal protrusions 309 that have a platform portion and are arranged periodically and continuously as shown in FIG. 3C.

Afterwards, an etching process like the transformer coupled plasma (TCP) is performed to expose a portion of the first conductive type semiconductor layer 315 by removing a portion of the second conductive type semiconductor layer 319 and a portion of the active layer 317, and then forming the first electrode 323 on the exposed portion of the first conductivity type semiconductor layer 315. The material of the first electrode 323 in the preferred embodiment of the present disclosure is selected from the group consisting of In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Au/Ni, Ni/Cr/Au, Ti/Pd/Au, Ti/Pt/Au, Ti/Al/Ni/Au, Au/Si/Ti/Au/Si, and Au/Ni/Ti/Si/Ti.

Later, a transparent conductive layer 325 is formed on the second conductive type semiconductor layer 319, and a second electrode 327 is formed on the transparent conductive layer 325. The material of the transparent conductive layer 325 in the preferred embodiment of the present disclosure is selected from the group consisting of the Indium Tin Oxide, Cadmium Tin Oxide, Zinc Oxide, Indium Oxide, Tin Oxide, Copper Aluminum Oxide, Copper Gallium Oxide, and Strontium Copper Oxide. The second electrode 327 material is selected from the group consisting of Au/Ni, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, Ni/In, and Pt₃In₇.

Afterwards, a reflector layer 329 is formed on the lower surface 305 of the micro-lens substrate 311 conformally with the geometric pattern 310 to compose a light-emitting diode device 300 as shown in FIG. 3D. In a preferred embodiment of the present disclosure the reflector layer 329 comprises a Distributed Bragg Reflector formed by a stack structure of multi-layered oxide films, a one dimension photonic crystal film and a metal material selected from the group consisting of Al, Au, Pt, Pb, Ag, Ni, Ge, In, Sn, and alloys thereof.

The light 331 emitted from the active layer 317 of the light-emitting diode device 300 is reflected by the reflector layer 329, and refracted through the arc surface of the concave portion 307, which can change the emitting angle and the emitting path. After the reflection and the refraction, the light emitting angle is larger than the critical angle between the interface of the transparent conductive layer 325 and the environment, so the light can emit outwardly. The light extraction efficiency of the light-emitting diode device 300 is therefore enhanced.

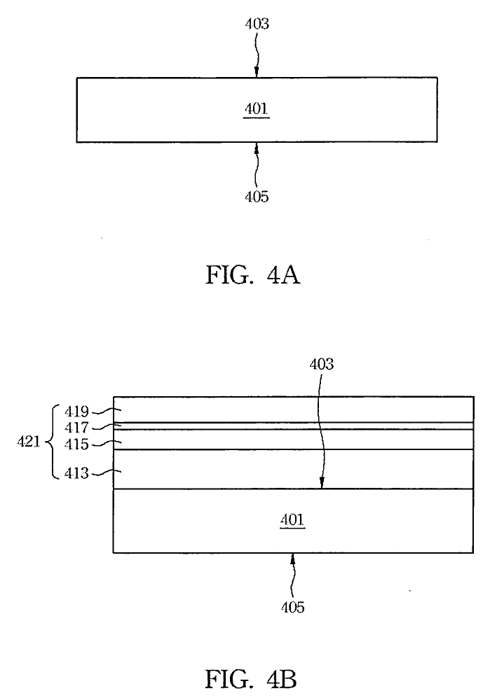

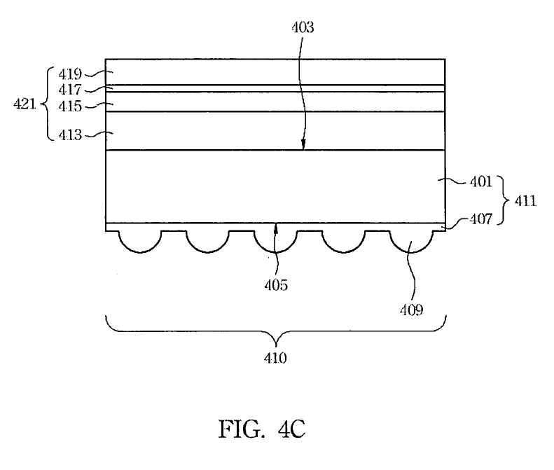

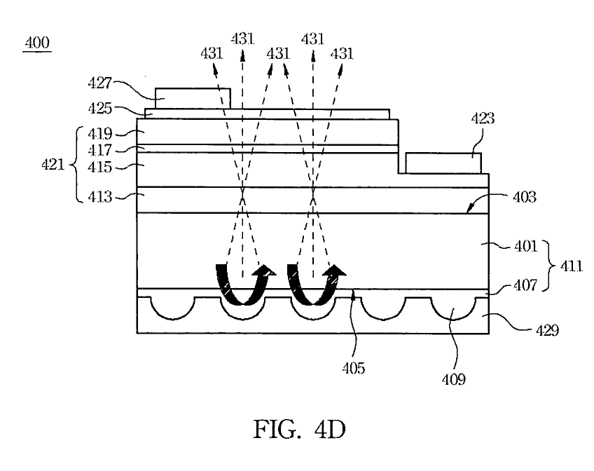

FIGS. 4A-4D are the series of processing section diagrams of the forth embodiment of the present disclosure related to a gallium nitride light-emitting diode device 400. First, FIG. 4A shows that a transparent substrate 401 having an upper surface 403 and a lower surface 405 is provided. As FIG. 4B shows that a buffer layer 413 is formed on the upper surface 403 of the transparent substrate 401 by a deposition method. In the preferred embodiment of the present disclosure, the buffer layer 413 is AlN or GaN.

Then growing a first conductivity type (for example n-type) semiconductor layer 415 on the buffer layer 413 by for example the metal organic chemical vapor deposition technology with the reaction gases like trimethylgallium (TMGa), trimethylaluminun (TMAl), trimethylindinum (TMIn), ammonia gas and the above gases arbitrarily combined, and adding an n-type dopant like silicon. The preferred material for the first conductivity type semiconductor layer is n-type AlGaInN or n-type GaN. Then growing an active layer 417 on the first conductivity type semiconductor layer 415 wherein the active layer 417 can be composed of AlGaInN and GaN multi-quantum wells (MQW) structure.

After forming the active layer, growing a second conductivity type (for example p-type) semiconductor layer 419 on the active layer 417 with the reaction gases like trimethylgallium (TMGa), trimethylaluminun (TMAl), trimethylindinum (TMIn), ammonia gas and the above gases arbitrarily combined, and adding a p-type dopant like magnesium. The above formation processes of the epitaxy structure on the micro-lens substrate are finished. Then a plurality of protruded particles 409 with transmitting and scattering function is formed on the lower surface 405 by deposition or adhesion process. In the preferred embodiment of the present disclosure, the plurality of protruded particles 409 is insulated and is deposited on the lower surface 405, and the material can be Silicon Oxide, Silicon Di-oxide and Silicon Nitride. In another embodiment of the present disclosure, the protruded particles 409 are fixed on a transparent film 407, and are adhered on the lower surface 405. The shape of the protruded particles 409 can be semi-sphere, pyramidal or trapezoid. These protruded particles 409 are continuously or discontinuously disposed to form a geometric pattern 410 on the lower surface 405. Every protruded particle 409 can be regarded as a micro-lens with scattering function, thus a micro-lens substrate 411 is formed by above mentioned processes. In this embodiment, the geometric pattern 410 is composed of a plurality of semi-sphere protruded particles 409 that are arranged periodically and continuously as shown in FIG. 4C.

Afterwards, an etching process like the transformer coupled plasma (TCP) is performed to expose a portion of the first conductive type semiconductor layer 415 by removing a portion of the second conductive type semiconductor layer 419 and a portion of the active layer 417, and then forming the first electrode 423 on the exposed portion of the first conductive type semiconductor layer. The material of the first electrode 423 in the preferred embodiment of the present disclosure is selected from the group consisting of In, Al, Ti, Au, W, InSn, TiN, WSi, PtIn₂, Nd/Al, Ni/Si, Pd/Al, Ta/Al, Ti/Ag, Ta/Ag, Ti/Al, Ti/Au, Ti/TiN, Zr/ZrN, Au/Ge/Ni, Cr/Au/Ni, Ni/Cr/Au, Ti/Pd/Au, Ti/Pt/Au, Ti/Al/Ni/Au, Au/Si/Ti/Au/Si, and Au/Ni/Ti/Si/Ti.

Later, a transparent conductive layer 425 is formed on the second conductive type semiconductor layer 419, and a second electrode 427 is formed on the transparent conductive layer 425. The material of the transparent conductive layer 425 in the preferred embodiment of the present disclosure is selected from the group consisting of the Indium Tin Oxide, Cadmium Tin Oxide, Zinc Oxide, Indium Oxide, Tin Oxide, Copper Aluminum Oxide, Copper Gallium Oxide, and Strontium Copper Oxide. The second electrode 327 material is selected from the group consisting of Au/Ni, NiO/Au, Pd/Ag/Au/Ti/Au, Pt/Ru, Ti/Pt/Au, Pd/Ni, Ni/Pd/Au, Pt/Ni/Au, Ru/Au, Nb/Au, Co/Au, Pt/Ni/Au, Ni/Pt, Ni/In, and Pt₃In₇.

Afterwards, a reflector layer 429 is formed on the lower surface 405 of the micro-lens substrate 411 to compose a light-emitting diode device 400 as shown in FIG. 4D. In a preferred embodiment of the present disclosure, the reflector layer 429 comprises a Distributed Bragg Reflector (DBR) formed by a stack structure of multi-layered oxide films, a one dimension photonic crystal film and a metal material selected from the group consisting of Al, Au, Pt, Pb, Ag, Ni, Ge, In, Sn, and alloys thereof.

The light 431 emitted from the active layer 417 of the light-emitting diode device 400 is reflected by the reflector layer 429, and refracted through the arc surface of the protruded particles 409 (micro-lens), which can change the emitting angle and the emitting path. After the reflection and the refraction, the light emitting angle is larger than the critical angle between the interface of the transparent conductive layer 425 and the environment, so the light can emit outwardly. The light extraction efficiency of the light-emitting diode device 400 is therefore enhanced.

Although specific embodiments have been illustrated and described, it will be apparent that various modifications may fall within the scope of the appended claims.

We claim:

1. A light-emitting diode device, comprising:
a substrate;
a plurality of micro-lens formed on an upper surface of the substrate;
a reflector formed on a lower surface of the substrate;
a first conductivity type semiconductor layer formed on the substrate;
an active layer formed on a partial area of the first conductivity type semiconductor layer;
a second conductivity type semiconductor layer formed on the active layer;
a first electrode formed on the other partial area of the first conductivity type semiconductor layer uncovered by the active layer; and
a second electrode formed on the second conductivity type semiconductor layer.

2. The light-emitting diode device according to claim 1, further including a transparent conductive layer formed between the second electrode and the second conductivity type semiconductor layer.

3. The light-emitting diode device according to claim 2, wherein the transparent conductive layer is selected from the group consisting of Indium Tin Oxide, Cadmium Tin Oxide, Zinc Oxide, Indium Oxide, Tin Oxide, Copper Aluminum Oxide, Copper Gallium Oxide, and Strontium Copper Oxide.

4. The light-emitting diode device according to claim 1, wherein the reflector layer is selected from the group consisting of a Distributed Bragg Reflector formed by a stack structure of multi-layered oxide films, a one dimension photonic crystal film, and a metal material.

5. The light-emitting diode device according to claim 1, wherein the substrate is a sapphire substrate.

6. The light-emitting diode device according to claim 1, wherein the micro-lens is selected from the group consisting of a plurality of protrusions on a partial area of the substrate and a plurality of protruded particles.

7. A light-emitting diode device, comprising:
a substrate;
a reflector formed on a lower surface of the substrate;
a plurality of micro-lens formed between the substrate and the reflector;
a first conductivity type semiconductor layer formed on an upper surface of the substrate;
an active layer formed on a partial area of the first conductivity type semiconductor layer;
a second conductivity type semiconductor layer formed on the active layer;
a first electrode formed on the other partial area of the first conductivity type semiconductor layer uncovered by the active layer; and
a second electrode formed on the second conductivity type semiconductor layer.

8. The light-emitting device according to claim 7, further including a transparent conductive layer formed between the second electrode and the second conductivity type semiconductor layer.

9. The light-emitting device according to claim 8, wherein the transparent conductive layer is selected from the group consisting of Indium Tin Oxide, Cadmium Tin Oxide, Zinc Oxide, Indium Oxide, Tin Oxide, Copper Aluminum Oxide, Copper Gallium Oxide, and Strontium Copper Oxide.

10. The light-emitting device according to claim 7, wherein the reflector layer is selected from the group consisting of a Distributed Bragg Reflector formed by a stack structure of multi-layered oxide films, a one dimension photonic crystal film, and a metal material.

11. The light-emitting diode device according to claim 7, wherein the substrate is a sapphire substrate.

12. The light-emitting diode device according to claim 7, wherein the micro-lens is selected from the group consisting of a plurality of protrusions on the partial area of the substrate and a plurality of protruded particles.

13. A method for fabricating a light-emitting diode device, comprising:
providing a substrate;
forming a plurality of micro-lens on an upper surface of the substrate;
forming a first conductivity type semiconductor layer on the substrate;
forming an active layer on the first conductivity type semiconductor layer;
forming a second conductivity type semiconductor layer on the active layer;
removing a portion of the second conductivity type semiconductor layer and a portion of the active layer to expose a portion of the first conductivity type semiconductor layer;
forming a first electrode on the exposed portion of the first conductivity type semiconductor layer;
forming a second electrode on the second conductivity type semiconductor layer; and
forming a reflector on a lower surface of the substrate.

14. The method for fabricating a light-emitting diode device according to claim 13, further forming a transparent conductive layer on the second conductivity type semiconductor layer before forming the second electrode.

15. The method for fabricating a light-emitting diode device according to claim 13, wherein forming a plurality of micro-lens on an upper surface of the substrate process including:
providing a transparent substrate; and
depositing a plurality of protruded particles on the upper surface of the transparent substrate.

16. The method for fabricating a light-emitting diode device according to claim 13, wherein forming a plurality of micro-lens on an upper surface of the substrate process including:
providing a transparent substrate; and
adhering a transparent film with a plurality of protruded particles on the upper surface of the transparent substrate.

17. The method for fabricating a light-emitting diode device according to claim 13, wherein forming a plurality of micro-lens on an upper surface of the substrate process including:
providing a transparent substrate; and
forming a plurality of protrusions by etching the upper surface of the transparent substrate.

18. A method for fabricating a light-emitting diode device, comprising:
providing a substrate;
forming a reflector on a lower surface of the substrate;
forming a plurality of micro-lens between the substrate and the reflector;
forming a first conductivity type semiconductor layer on an upper surface of the substrate;
forming an active layer on a partial area of the first conductivity type semiconductor layer;
forming a second conductivity type semiconductor layer on the active layer;
removing a portion of the second conductivity type semiconductor layer and a portion of the active layer to expose a portion of the first conductivity type semiconductor layer;
forming a first electrode on the exposed portion of the first conductivity type semiconductor layer; and
forming a second electrode on the second conductivity type semiconductor layer.

19. The method for fabricating a light-emitting diode device according to claim 18, further forming a transparent conductive layer on the second conductivity type semiconductor layer before forming the second electrode.

20. The method for fabricating a light-emitting diode device according to claim 18, wherein forming a plurality of micro-lens on a lower surface of the substrate process including:
providing a transparent substrate; and
depositing a plurality of protruded particles on the upper surface of the transparent substrate.

21. The method for fabricating a light-emitting diode device according to claim 18, wherein forming a plurality of micro-lens on a lower surface of the substrate process including:
providing a transparent substrate; and
adhering a transparent film with a plurality of protruded particles on the upper surface of the transparent substrate.

22. The method for fabricating a light-emitting diode device according to claim 18, wherein forming a plurality of micro-lens on a lower surface of the substrate process including:
providing a transparent substrate; and
forming a plurality of protrusions by etching the upper surface of the transparent substrate.
